(19) United States
(12) Patent Application Publication
(10) Pub. No.: US 2008/0025007 A1
(43) Pub. Date: Jan. 31, 2008

(54) Partially plated through-holes and achieving high connectivity in multilayer circuit boards using the same

(75) Inventor: Eric Rong Ao, Ottawa (CA)

Correspondence Address: YOUNG LAW FIRM, P.C.;ALAN W. YOUNG, 4370 ALPINE ROAD, SUITE 106, PORTOLA VALLEY, CA, 94028, US

(73) Assignee: Liquid Computing Corporation, Ottawa (CA)

(21) Appl. No.: 11/460,554

(22) Filed: Jul. 27, 2006

(51) Int. Cl. H05K 7/00

(52) U.S. Cl. 361/760

(57) ABSTRACT

A multilayer midplane board has a front side and a back side and includes a first partially plated through-hole; a second partially plated through-hole spaced away from the first partially plated through-hole, and a first conductive signal track that electrically couples a selected plated section of the first partially plated through-hole directly adjacent the front side to a selected plated section of the second partially plated through-hole adjacent the back side.

### BACKGROUND OF THE INVENTION

1. Field of the Invention

Embodiments of the present invention relate generally to multilayer circuit boards and, more particularly, to multilayer midplane boards providing high connectivity with high speed signals.

2. Description of the Prior Art and Related Information

Conventional packaging of electronic systems in equipment racks, with electronic components mounted on modules (e.g. printed circuit boards), plugged into a vertically placed passive back plane, has been known for many years. In such systems, connectors mounted on the back plane mate with connectors at the edge of each of the modules. Among a number of possible mechanical configurations, a pin and box connector configuration is often used in systems where high signal integrity is required and where high signal frequencies occur. The pins of the connectors extend into or through plated holes in the back plane. The back plane may be manufactured as a laminated board in the form of a number of layers of an insulating material, with conductive tracks on the outside as well as between each of the layers. The conductive tracks are formed so as to provide electrical circuits between the plated holes, and thus the pins to which the circuitry on the printed circuit boards are connected.

Among numerous variations of the basic multilayer circuit board that have been developed, are for example: surface mounted connectors to allow more space for routing tracks within the back plane; through-vias to interconnect the tracks on different layers of the multilayer back plane; buried and micro-vias to optimize space for routing tracks; and others.

An extension of the single-sided back plane is the double-sided back plane or “midplane” that allows circuit boards to be inserted from both sides, e.g. the front and the back side of a chassis. A simple application of a midplane is to support Input/Output (I/O) modules plugged into the back side of the midplane, and logic modules plugged in the front side of the midplane. The logic modules may be connected to each other through a bus and some or all of the midplane connector pins extend through the midplane, thus providing connectivity between matching frontside and backside modules very simply, and without the need for additional routing tracks.

While bus-like connectivity between modules, i.e. a number of modules sharing the same signals, is often used, architectures based on point-to-point connections may provide higher overall interconnect capacity (number of signals multiplied by their speed), and are thus frequently used in switching systems, or other systems where a full mesh interconnect is required. Furthermore, each point-to-point connection is capable of higher signal speed than a bus connection, but point-to-point connections in a multilayer back plane or midplane require more space because they must thread between the through-holes that house the connector pins.

A particularly demanding application is a high performance computer system in which a midplane is populated on both sides with computing modules and I/O modules, and where all computing modules are connected with high speed signals in a full mesh to each other as well as to the I/O modules. Multilayer backplane technology has evolved over the years, and numerous techniques for increasing their density and interconnect capacity have been proposed.

A midplane that supports orthogonal plug-in modules could automatically provide full mesh connections between each of the frontside modules with each of the backside modules, but not easily between modules on the same side of the midplane. Such an arrangement (of vertically and horizontally oriented plug-in modules) would further have mechanical disadvantages in the areas of: insertion and removal of modules; cooling; restriction on aspect ratio, especially if the same type of module should fit on either side of the midplane without modification.

A recently developed manufacturing technique, described in “Deep Microvia's in Next Generation System Design” by Leigh Eichel, International Cadence Usersgroup Conference, Manchester, N.H., Sep. 15-17, 2003, provides a capability for high density interconnect in a multilayer midplane, including electrically isolated vias (EIV) which enable a single through-hole to support two electrically distinct signals.

What are needed are methods and systems for achieving even higher connectivity in a multilayer midplane board, permitting full mesh interconnection of plug-in modules, without requiring orthogonal placement of modules.

### SUMMARY OF THE INVENTION

Accordingly, an embodiment of the present invention is a circuit board having a first side and a second side, a distance between the first and second sides defining a thickness of the circuit board. The circuit board may include a first surface defining a first through-hole extending from the first to the second side; a first conductive layer disposed adjacent to the first side and covering the first surface over a first distance that is greater than half but less than the thickness of the circuit board; a second surface defining a second through-hole that extends from the first to the second side and that is spaced away from the first through-hole; a second conductive layer disposed adjacent to the second side covering the second surface over a second distance that is less than the thickness of the circuit board, and a conductive signal track that directly electrically couples the first conductive layer to the second conductive layer.

According to further embodiments, the conductive signal track may be oriented substantially parallel to the first and/or second sides. At least a part of the first conductive layer may overlap a part of the second conductive layer. At least a portion of the first surface that is not covered by the first conductive layer may be electrically non-conductive. The circuit board may further include a third conductive layer disposed adjacent to the second side and covering the first surface over a third distance that is less than the thickness of the circuit board. The electrically non-conductive portion of the first surface may be disposed between the first and third conductive layers. At least a portion of the second surface that is not covered by the second conductive layer may be electrically non-conductive. The circuit board may further include a fourth conductive layer disposed adjacent to the first side and covering the second surface over a fourth distance that is less than the thickness of the circuit board. The electrically non-conductive portion of the second surface may be disposed between the second and fourth conductive layers. The circuit board may further include a first connector including a first conductive element and a second connector including a second conductive element, the first conductive element may be disposed within the first through-hole and electrically coupled to the first conductive layer and the second conductive element may be disposed within the second through-hole and electrically coupled to the second conductive layer. The first conductive element may include a first pin and the second conductive element may include a second pin. The circuit board may be a multilayer midplane. The conductive signal track may be configured to electrically couple the first conductive layer to the second conductive layer without an intervening fully plated through hole.

According to another embodiment thereof, the present invention is a multilayer midplane board having a front side and a back side. The multilayer midplane board may include a first partially plated through-hole; a second partially plated through-hole spaced away from the first partially plated through-hole, and a first conductive signal track electrically coupling a selected plated section of the first partially plated through-hole directly adjacent the front side to a selected plated section of the second partially plated through-hole adjacent the back side.

The multilayer midplane board may further include: a first connector including a first conductive element inserted into the first partially plated through-hole from the front side, and a second connector including a second conductive element inserted into the second partially plated through-hole from the back side, the first conductive signal track electrically coupling the first conductive element to the second conductive element. The first partially plated through-hole may extend from the front side to the back side and may include a first conductive layer adjacent the front side and a second conductive layer adjacent the back side and a first non-conductive region between the first and second conductive layers. The second partially plated through-hole may extend from the front side to the back side and may include a third conductive layer adjacent the front side and a fourth conductive layer adjacent the back side and a second non-conductive region between the third and fourth conductive layers. The first partially plated through-hole and the second partially plated through-holes may be configured such that the first conductive signal track may be disposed substantially parallel to the front and/or back sides. At least one of the selected plated section of the first partially plated through-hole and the selected plated section of the second partially plated through-hole may extend over a distance that is greater than half but less than the thickness of the multilayer midplane board. The multilayer midplane board may further include a fully plated through-hole extending between the front and back sides. The first partially plated through-hole may include a first plated section, a second plated section and a first insulated section between the first and second plated sections. The first plated section may have the same length as the length of the second plated section. The first plated section may be longer than the second plated section. The second partially plated through-hole may include a third plated section, a fourth plated section and a second insulated section between the third and fourth plated portions. The third plated section may have the same length as the length of the fourth plated section. The third plated section may be longer than the fourth plated section. The first partially plated through-hole may include a plated section adjacent the front side, the second partially plated through-hole may include a plated section adjacent the back side, and the sum of the lengths of the plated sections may be greater than the thickness of the multilayer midplane by at least a thickness of the first conductive signal track.

According to yet another embodiment, the present invention is a computer that includes a plurality of compute modules; an I/O module; a multilayer midplane board including a front side and a back side, selected ones of the plurality of compute modules being coupled to the front side through respective front side connectors and selected other ones of the plurality of compute modules and the I/O module being coupled to the back side through respective back side connectors. The multilayer midplane board may include a plurality of partially plated through-holes extending between the front and back sides of the multilayer midplane, each of the plurality of partially plated through-holes including a first conductive section, a second conductive section and an insulating section between the first and second conductive sections, and a plurality of conductive signal tracks, each electrically coupling one of the first and second conductive sections of a selected one of the plurality of partially plated through-holes to one of the first and second plated sections of another one of the plurality of selected partially plated through-holes to electrically couple a selected one of the front side connectors to a selected one of the back side connectors.

The first conductive sections may be disposed adjacent the front side and the second conductive sections may be disposed adjacent the back side of the multilayer midplane board. Each of the front side connectors and the back side connectors may include at least one conductive element inserted into one of the plurality of partially plated through-holes. The plurality of partially plated through-holes may be configured such that the plurality of conductive signal tracks are disposed substantially parallel to at least one of the front and back sides. The multilayer midplane board may further include at least one fully plated through-hole extending between the front and back sides to directly electrically couple at least one selected front side connector to at least one selected back side connector. The multilayer midplane board may further include at least one fully plated through-hole extending between the front and back sides to directly electrically couple at least one selected front side connector to at least one selected back side connector such that each one of the plurality of compute and the I/O modules is electrically coupled to each of the other of the plurality of compute and the I/O modules. Each of the plurality of partially plated through-holes may include a first plated section, a second plated section and a first insulated section between the first and second plated sections. The first plated section may have the same length as the length of the second plated section. The first plated section may be longer than the second plated section. At least one selected plated section of one of the plurality of partially plated through-holes may extend over a distance that is greater than half but less than the thickness of the multilayer midplane board.

Yet another embodiment of the present invention is a multilayer midplane board having a first side and a second side, the multilayer midplane board including a first partially plated through-hole including a first plated section adjacent the first side, a second plated section adjacent the second side and a first insulated section between the first plated section and the second plated section; a second partially plated through-hole including a third plated section adjacent the first side, a fourth plated section adjacent the second side and a second insulated section between the third plated section and the fourth plated section; a first conductive signal track electrically coupled to the first plated section and the fourth plated section, and a second conductive signal track electrically coupled to the second plated section;

A third conductive signal track may be electrically coupled to the third plated section, and the first, second and third conductive signal tracks may be electrically isolated from one another. The multilayer midplane board may further include a first connector including a first conductive element inserted into the first partially plated through-hole from the first side, and a second connector including a second conductive element inserted into the second partially plated through-hole from the second side, the first conductive signal track electrically coupling the first conductive element to the second conductive element. The multilayer midplane board may further include a first connector including a first conductive element inserted into the first partially plated through-hole from the first side, and a second connector including a second conductive element inserted into the second partially plated through-hole from the first side, the second conductive signal track electrically coupling the first conductive element to the second conductive element. At least one of the first and fourth plated sections may extend over a distance that is greater than half but less than the thickness of the multilayer midplane board. The multilayer midplane board may further include a fully plated through-hole extending between the first and second sides. The first plated section may have the same length as the length of the second plated section. The first plated section may be longer than the second plated section. The third plated section may have the same length as the length of the fourth plated section. The third plated section may be longer than the fourth plated section. The sum of the lengths of the first and second plated sections may be greater than the thickness of the multilayer midplane by at least a thickness of the first conductive signal track.

### BRIEF DESCRIPTION OF THE DRAWINGS

To facilitate a more full understanding of the present invention, reference is now made to the appended drawings. These drawings should not be construed as limiting the present invention, but are intended to be exemplary only.

FIG. 1 is a system diagram of an exemplary high performance computer (HPC) system based on computing modules and I/O modules in which embodiments of the present invention may be used.

FIG. 2 is a cross-sectional view of a midplane assembly, including a midplane board having a front side and a back side, according to an embodiment of the present invention.

FIG. 3 is a cross-sectional diagram of a portion of the midplane board of FIG. 2, showing routings of signals between selected connector pins, according to an embodiment of the present invention.

FIG. 4 is a cross-sectional diagram of another portion of the midplane board, according to an embodiment of the invention.

FIG. 5 shows another implementation of the HPC system of FIG. 1, according to another embodiment of the present invention.

### DETAILED DESCRIPTION

High performance computer (HPC) systems include a large number of computing modules that are able to communicate with each other through a high capacity interconnect facility, such as a packet switching network, or by means of direct module-to-module interconnection. Some HPC system architectures incorporate a structure such as a torus or tree connectivity in which some computing modules may serve as forwarding nodes for communications between other computing modules that are not directly connected to each other.

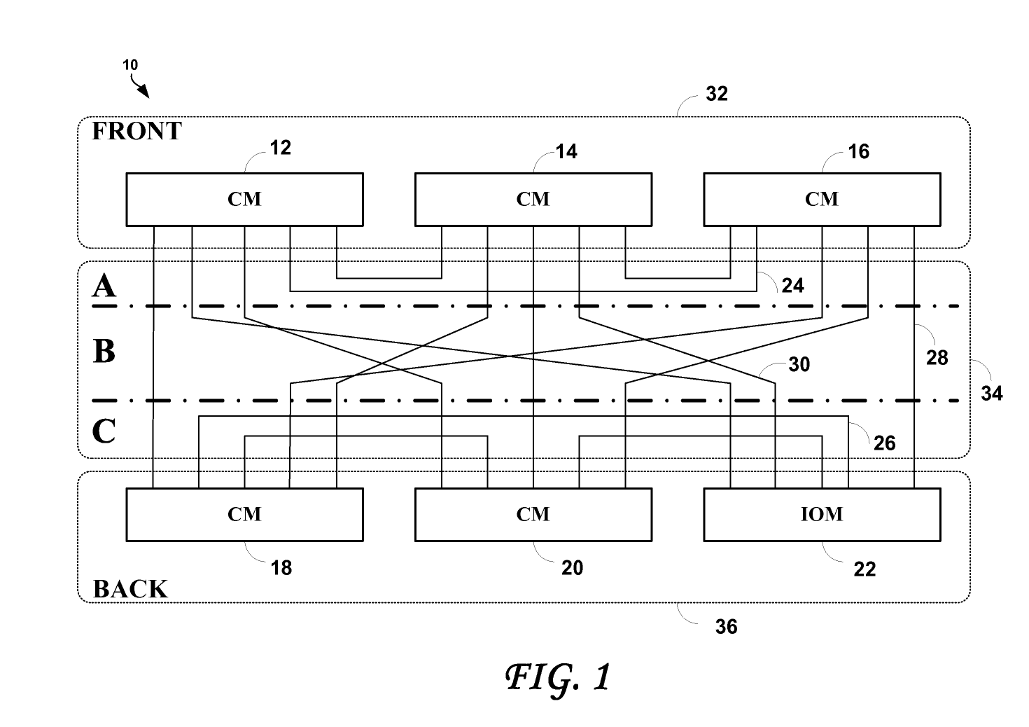

FIG. 1 is a system diagram of an exemplary high performance computer (HPC) system 10 based on computing modules and I/O modules in which embodiments of the present invention may be used to great advantage. In the simplified example shown in FIG. 1, only five computing modules and a single I/O module are shown for clarity. A realistic HPC system of course would contain many more modules. Embodiments of the present invention enable the design and manufacture of a midplane that provides for connecting in a full mesh configuration all computing modules and provides for full connectivity between the computing modules and I/O modules, within the confines of a double sided chassis and a single midplane. Co-pending and commonly assigned U.S. application Ser. No. 60/736,106, Kemp et al., “Methods and systems for scalable interconnect”, which application is hereby incorporated herein by reference in its entirety, describes methods and systems for scalable interconnect within a single chassis, and with multiple chassis.

The HPC system 10 of FIG. 1 includes five computing modules (hereafter, “CM”) 12, 14, 16, 18, 20, and an I/O module (hereafter, “IOM”) 22. In the HPC system 10, each of the modules (CM 12-20, IOM 22) is shown connected to every other module with one link where each link represents a parallel set of N wires. In general, the number of modules in an HPC system of the type illustrated in FIG. 1 may be designated as “M.” The total number of links “L” required to implement a full mesh interconnect may be calculated as L=M×(M−1). The corresponding number of link wires “W” to provide the full mesh interconnect where each link comprises N wires is thus W=L×N.

For clarity, only some of the links are labeled with reference numerals, i.e. a link 24 (between the CM 12 and the CM 16), a link 26 (between the CM 18 and the IOM 22), a link 28 (between the CM 16 and the IOM 22), and a link 30 (between the CM 14 and the IOM 22). For the purpose of the illustration, it is assumed that the CMs 12, 14, and 16 are physically located in a region “FRONT” 32 on one side of a midplane 34, while the CMs 18 and 20, and the IOM 22 are physically located in a region “BACK” 36 on the other side of the midplane 34. The midplane 34 includes three notional zones “A”, “B”, “C.” The zone “A” is adjacent to the “FRONT” 32, the zone “C” is adjacent to the “BACK” 36, while the zone “B” is between the zones “A” and “C”, and is not adjacent to either the “FRONT” region 32 or the “BACK” region 36.

A number of links may be disposed entirely within the zone “A” of the midplane 34. These are the links between the CMs 12, 14, and 16 in the “FRONT” region 32. The link 24 between the CM 12 and the CM 16 is representative of these links. Similarly, a number of links may be disposed entirely within the zone “C” of the midplane 34. These are the links between the CMs 18 and 20, and the IOM 22 in the “BACK” region 36. The link 26 between the CM 18 and the IOM 22 is representative of these links. All other links extend between a module in the “FRONT” region 32 (one of the CMs 12, 14, and 16) and a module in the “BACK” region 36 (one of the CMs 18 and 20, or the IOM 22). These links must cross the middle portion of the midplane 34, i.e. the zone “B.” The link 28 between the CM 16 and the IOM 22, and the link 30 between the CM 14 and the IOM 22, are representative of such links.

In a representative embodiment of an HPC system that incorporates embodiments of the present invention, each link may represent an Infiniband high speed serial link (whose specification is maintained by the InfiniBand Trade Association IBTA) with four lanes of differential signals in each direction, thus N=16. It is to be noted, however, that embodiments of the present invention are not limited to the Infiniband interconnect protocol, as different embodiments of the present invention may be implemented using other interconnect protocols, as those of skill in this art may recognize. In the same representative embodiment, ten modules may be plugged into each side of the midplane, thus the number of modules M=20. The resulting number of links to achieve full-mesh interconnect is then L=20×19=380, and the corresponding number of link wires (signals, or PCB tracks in the midplane 34) to provide the full mesh interconnect in this embodiment is thus W=16×380=6080. It will be appreciated that the HPC system further requires additional signals such as control and clock signals, and that the routing of all these signals constitutes a considerable challenge.

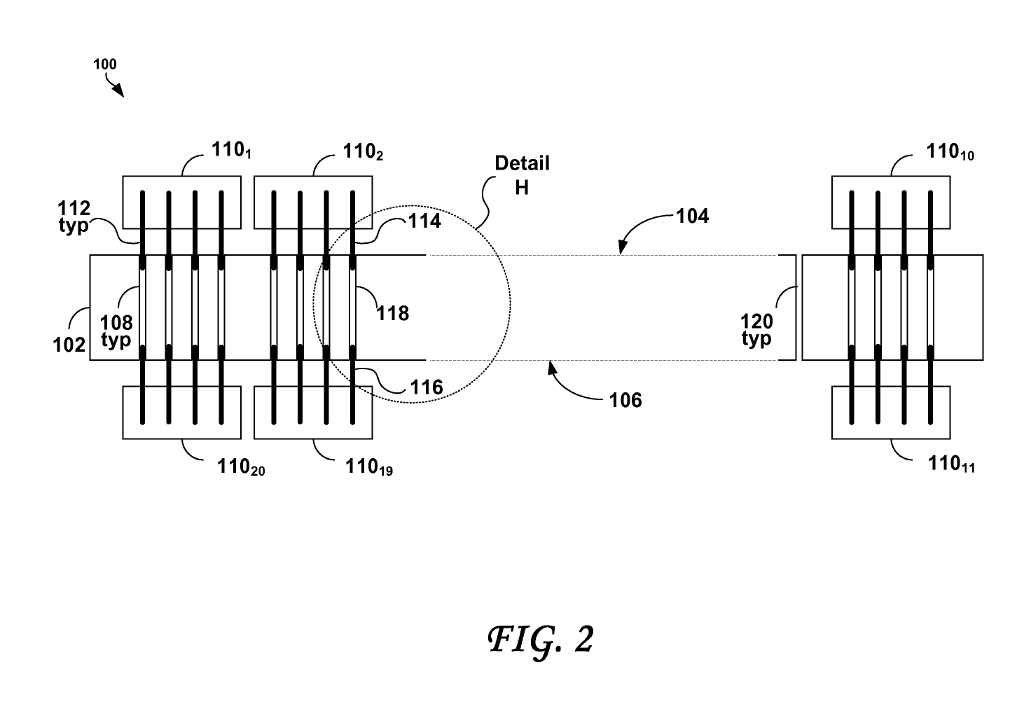

According to embodiments of the present invention, the midplane may be equipped with connectors on both the front and back sides 32, 36 of the midplane 34. FIG. 2 is a cross-sectional view of a midplane assembly 100, including a midplane board 102 having a front side 104 and a back side 106. The midplane board 102 may be perforated with a number of through-holes 108. The exemplary midplane assembly 100 of FIG. 2 further includes a number M (M=20) of high density connectors 110j, where the subscript j ranges from 1 to 20. Each connector 110ⱼ is attached to the midplane board 102, the connectors 110₁ to 110₁₀ occupying the front side 104, and the connectors 110₁₁ to 110₂₀ occupying the back side 106 of the midplane board 102. Each connector 110ⱼ includes pins 112, one end each of which is inserted in a matching through-hole 108. The other end of each pin 112 may be attached to a receptacle (not shown) for a corresponding pin (not shown) of a mating connector (not shown) that is mounted on a plug-in module. As embodiments of the present invention are directed to the midplane, the module plug-in side of the connectors is not described further herein.

Various high density high speed connectors, for example the GbX compliant pin connector manufactured by the Amphenol Corporation of Wallingford, Conn. may be suitable for use in conjunction with embodiments of the present invention. Such connectors allow for a very large number of pins, including signal pins and ground pins. The sketch of the midplane assembly 100 is not an engineering drawing, it is not to scale, and it is simplified, omitting many mechanical details, in order to more clearly show aspects of embodiments of the present invention.

Returning now to FIG. 2, note that the connector 110₁ is shown to be mounted opposite the connector 110₂₀, and the connector 110₁₀ is shown to be mounted opposite the connector 110₁₁. Opposing connectors share the through-holes 108 in the midplane board 102 as illustrated in the detail “H” in the FIG. 2. The detail “H” includes portions of the opposing connectors, 110₂ having a pin 114, and 110₁₉ having a pin 116, and a section of the midplane board 102 including a through-hole 118. The pin 114 of the connector 110₂ extends only part way into the through-hole 118 from the front side 104 of the midplane board 102, while the pin 116 of the connector 110₁₉ also extends part way into the same through-hole 118 but from the back side 106. In addition to the through-holes 108 for receiving the connector pins 112, there may be via holes 120 (only one shown), which are simple through-holes from the front side 104 to the back side 106 of the midplane board 102. The midplane board 102 may include predetermined conductive signal layers that are electrically insolated from each other. The connectivity of the midplane board 102, that is the required signal connections between all connector pins 112 inserted in it, is commonly provided by plated/etched signal patterns of the conductive layer and by conductively plated via holes 120. The midplane assembly 100 of FIG. 2 may be realized, for example, by making use of the micro via technology described in the above referenced document “Deep Microvia's in Next Generation System Design.” Using such micro via technology, the through-holes 112 may be partially plated through from each side (front and back sides 104 and 106 respectively) of the midplane board 102. Each of the via holes 120 may also be partially plated through, in effect thus providing two independent vias, one adjacent to the front side 104, the other adjacent to the back side 106. Alternatively, a via hole 120 may be plated all the way through to form a fully plated through hole.

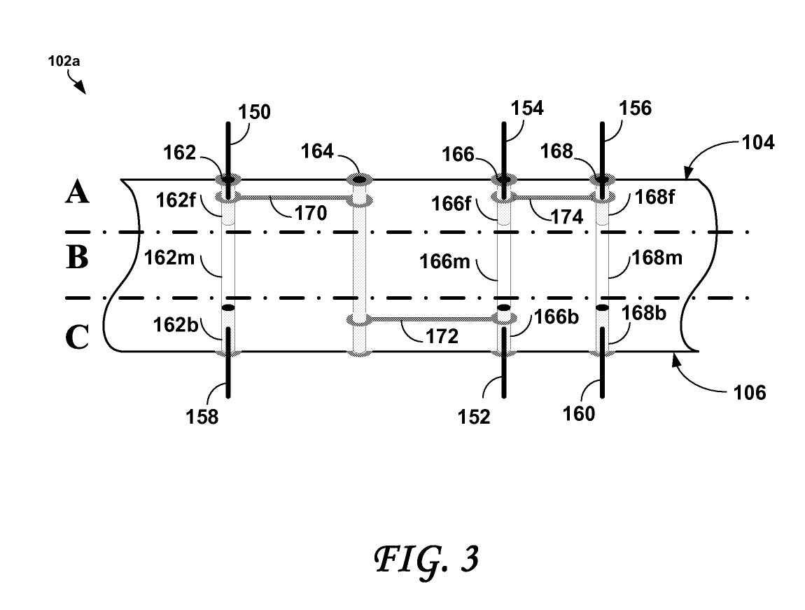

FIG. 3 is a cross-sectional diagram of a portion 102a of the midplane board 102, showing the routing of signals between selected connector pins 150 and 152, and between selected connector pins 154 and 156, according to an embodiment of the present invention. Connector pins 158 and 160 are shown for illustrative purposes. The midplane board 102 includes through-holes 162, 164, 166, and 168. Three zones (“A”, “B”, and “C”) of the midplane board 102 are indicated, corresponding to zones “A” to “C” in FIG. 1. The zone “A” is adjacent to the front side 104 of the midplane board 102, the zone “C” is adjacent to the back side 106 of the midplane board 102, while the zone “B” is between the zones “A” and “C”, and is not adjacent to either the front side 104 or the back side 106. Also illustrated are three conductive signal tracks 170, 172, and 174. The through-hole 164 is fully plated (made conductive) through its entire length, and serves as a conventional via. Each of the remaining through-holes (162, 166, and 168) defines three sections (indicated by suffixes “f”, “m”, and “b”), along their length: front sections (162f, 166f, and 168f respectively) and back sections (162b, 166b, and 168b respectively) are conductive, while middle sections (162m, 166m, and 168m respectively) are electrically non-conductive (e.g., insulated).

FIG. 3 shows the connector pins 150 to 160 inserted into the conductive front or conductive back sections of the through-holes 162, 166, and 168 as follow:
the connector pin 150 in the front conductive section 162f of the through-hole 162;
the connector pin 152 in the back conductive section 166b of the through-hole 166;
the connector pin 154 in the front conductive section 166f of the through-hole 166;
the connector pin 156 in the front conductive section 168f of the through-hole 168;
the connector pin 158 in the back conductive section 162b of the through-hole 162, and
the connector pin 160 in the back conductive section 168b of the through-hole 168.

The conductive signal tracks join the conductive sections of the through-holes as follow:
the signal track 170 joins the front conductive section 162f to the fully plated through-hole 164;
the signal track 172 joins the fully plated through-hole 164 to the back conductive section 166b, and
the signal track 174 joins the front conductive section 166f to the front conductive section 168f.

As a result, there is a conductive path from the connector pin 150 to the connector pin 152, by the following conductive path:
the front conductive section 162f of the through-hole 162;
the conductive signal track 170;
the fully plated through-hole 164;
the signal track 172; and
back conductive section 166b of the through-hole 166.

By means of the above-listed structures, an electrical connection is made between the connector pins 150 and 152, even though they are on opposite sides of the midplane board 102. When an electrical connection is required between two connector pins that are on the same side of the midplane board 102, no via (a through-hole that is conductive across its entire length) is necessary and a connection may be made directly. This is illustrated in FIG. 3 with a connection between the connector pins 154 and 156, by way of a conductive path formed from the front conductive section 166f of the through-hole 166, the signal track 174, and the front conductive section 168f of the through-hole 168. Even when an electrical connection is required between two connector pins on the same side of the midplane board 102, it may not be possible to route a signal track in a single layer because of the presence (congestion) of other signal tracks in the single layer. In that case it becomes necessary to employ another via in order to accomplish the routing. Those conversant with the design (layout) of the routing in a high-density backplane or midplane may appreciate that vias, while often necessary to achieve routing, consume space and thus contribute to the congestion that makes routing more difficult.

In a midplane for an HPC system as described above, the connections carry very high speed signals which must be routed as directly as possible, and the electro-magnetic discontinuities associated with vias should be avoided as much as possible. The interconnect methods and structures described above may be used to implement a midplane assembly (e.g. the midplane assembly 100, FIG. 2) for a system such as the HPC system 10 (FIG. 1). The required high connector density can be achieved because the connectors (110) may be mounted close to each other on both sides of the midplane board (102), and the desired full-mesh connectivity between all connectors on both sides of the midplane board (102) may be achieved, using multiple signal layers and vias.

For example, the connection between the connector pins 150 and 152 shown in FIG. 3 is illustrative of the connection 30 in FIG. 1, which connection crosses the midplane 34 from the CM 14 to the IOM 22. Generally, each connection that crosses the zone “B” in FIG. 1, (i.e. between connectors on opposing sides of the midplane 34) would require at least one via, analogous to the connection between the pins 150 and 152 illustrated in FIG. 3. Similarly, connections between connectors on the same side of the midplane 34 (i.e., those connections that are confined to the zones “A” and “C” in FIG. 1) may be made without the use of a via, such as the connection between the pins 154 and 156 illustrated in FIG. 3.

However, the use of high density connectors, combined with the high density (close) mounting of these connectors on both sides of the midplane board, leaves limited space for routing, and the presence of many vias makes the situation worse. In order to obtain a higher interconnect capacity for the HPC system, it is important to eliminate vias (fully plated through holes), or at least significantly reduce the number thereof. The elimination or reduction in the number of vias could then be exploited to provide the compound benefit of a greater number of signals and higher signal speed.

Note that the length of the front conductive sections and back conductive sections of the through-holes 162 and 166 are essentially equal. That is the reason that a fully plated through-hole 164 is needed for connectivity between connector pins 150 and 152.

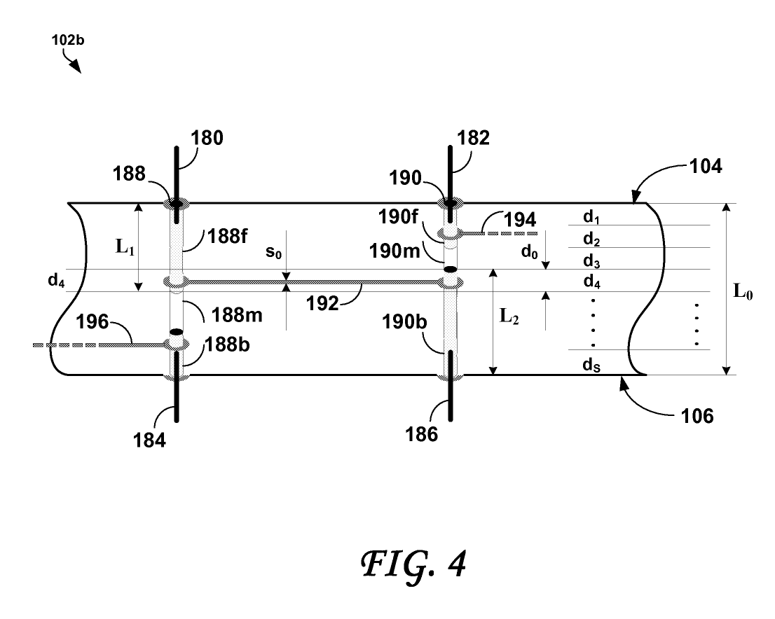

FIG. 4 is a cross-sectional diagram of another portion 102b of the midplane board 102, according to an embodiment of the invention. The embodiment of FIG. 4, as is described below, enables the elimination of vias for connections between connectors on opposing sides of the midplane board. The cross-sectional diagram of the portion 102b of the midplane board 102 shows selected connector pins 180, 182, 184, and 186, and through-holes 188 and 190. Each of the through-holes 188 and 190 defines front, middle, and back sections (suffixes “f”, “m”, and “b”, respectively). Analogous to the sections of the through-hole 162 (FIG. 3), the front conductive sections 188f and 190f, as well as the back conductive sections 188b and 190b, may be made electrically conductive (plated with an electrically conductive layer, for example), while the middle sections 188m and 190m of the through-holes 188 and 190 may be electrically insulated.

The connector pins 180 to 186 are inserted into the front conductive or back conductive sections of the through-holes 188 and 190, as follow:
the connector pin 180 in the front conductive section 188f of the through-hole 188;
the connector pin 182 in the front conductive section 190f of the through-hole 190;
the connector pin 184 in the back conductive section 188b of the through-hole 188; and
the connector pin 186 in the back conductive section 190b of the through-hole 190.

The multilayer midplane board 102 has a thickness L0, and includes a number “S” slices d₁ to d_{S}, each slice including a signal (or ground) layer and a dielectric (insulating) layer. The slices may be of differing thicknesses, or be of equal thickness. For simplicity of the description, the slices d₁ to d_{S} are of the same thickness (which thickness may be defined as d₀=L₀/S, where L₀ is the thickness of the midplane board 102), and include a signal (or ground) layer of thickness s₀.

A signal track 192 is located in the signal layer of one of the slices, a common signal layer d₄ in the example shown in the FIG. 4. Other signal tracks 194 and 196 are shown, occupying other signal layers. Specifically, the signal track 194 may occupy a signal layer that is between the front side 104 and the common signal layer d4, and the signal track 196 may occupy a signal layer that is between the common signal layer d4 and the back side 106 of the midplane board 102.

As shown in this exemplary implementation of the embodiment of FIG. 4, the length L₁ of the front section 188f of the through-hole 188 is such that the front conductive section 188f extends from the front side 104 of the midplane board 102 at least to the common signal layer d4. Similarly, the length L2 of the back conductive section 190b of the through-hole 190 is such that the back conductive section 190b extends from the back side 106 of the midplane board 102 at least to the common signal layer d4. Such structures enable the front conductive section 188f and the back conductive section 190b of the through-hole 190 to be directly joined by the signal track 192 in the common signal layer d4 without a via that extends from the front side 104 to the back side 106 of the midplane board 102. Indeed, as shown in FIG. 4, there is a conductive path from the connector pin 180 to the connector pin 186, by way of a conductive path formed from the front conductive section 188f of the through-hole 188, the conductive signal track 192, and the back conductive section 190b of the through-hole 190. The overlap of the front conductive section of a through-hole with the back conductive section of another through-hole can be ensured if the length of the front conductive section of the first through-hole (L₁) added to the length of the back conductive section of the second through-hole (L₂) exceeds the thickness of the midplane board (L₀) by at least the thickness s₀ of the signal layer of one slice. This requirement may also be stated as follows: (L₁+L₂)≧(L₀+s₀).

The signal tracks 194 and 196 may provide connections from the front conductive section 190f of the through-hole 190, and the back conductive section 188b of the through-hole 188 respectively, to other connectors (not shown) of the midplane board 102.

As may be appreciated, embodiments of the present invention enable the full mesh connectivity of FIG. 1 to be achieved entirely without the use of vias, by an appropriate choice of signal points (connector pins). It is to be noted that vias, although not necessary, may be used in conjunction with the embodiments of the present invention described herein.

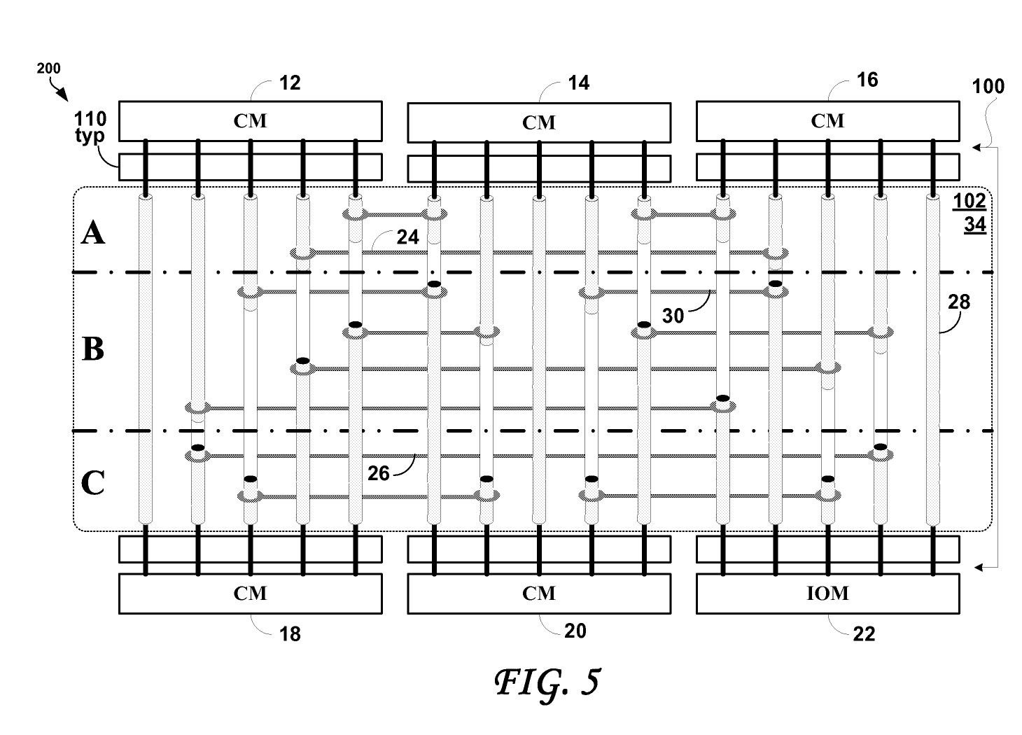

One such arrangement is illustrated in FIG. 5 which shows a possible physical realization 200 of the HPC system 10 of FIG. 1, based on the midplane assembly 100 of FIG. 2. The same reference numerals are used where applicable, as in the earlier figures. The (physical) midplane 102 corresponds to the (conceptual) midplane 34, and includes the zones “A”, “B”, and “C”, as described above. Each zone may correspond to one or more signal layers in the multilayer midplane. Each of the modules 12 to 22 is connected to the midplane 34 through a multi-pin connector 110. The connections within the midplane 34 may be implemented as:
a “straight through” connection in a single via (e.g., a conductively plated through-hole spanning the entire thickness between the front and the back of the midplane board 102) between pairs of modules that are directly opposite each other, such as shown between CM 12 and CM 18, between CM 14 and CM 20, and between CM 16 and IOM 22. An example of such a connection is connection 28;
a direct connection between the front conductive sections of two through-holes (between CM 12, 14, and 16), for example the connection 24;
a direct connection between the back conductive sections of two through-holes (between CM 18, 20, and the IOM 22), for example the connection 26; or
a direct connection between the front conductive section of one through-hole and the back conductive section of another through-hole (CM 12 to CM 20 and IOM 22, CM 14 to CM 18 and IOM 22, and CM 16 to CM 18 and CM 20) such as shown, for example, at connection 30.

A “straight through” connection using a single via exists where a through-hole with connector pins inserted at each end, is plated (made conductive) throughout its whole length, without an electrically isolated middle section. In that case, two connector pins are inserted into the same via, from opposing sides of the midplane (as shown at reference numeral 28 in FIG. 5). Such “straight through” connection using a single via may be used when module inputs and outputs can be arranged to line up across opposing front and back sides of the midplane board. For example the connection 28 is achieved with just such a “straight through” conductive path.

As may be appreciated, it is possible to obtain a high number of connections in a multilayer midplane by using electrically insulated via (EIV) technology, in combination with variable length plating of EIV through-holes such that the conductive front and back lengths of a front side and a back side signal respectively, overlap on a common signal layer, thus permitting connections between front side and back side signals to be accomplished without the use of additional via through-holes. By taking advantage of the necessary through-holes that are needed in any case, for the insertion of connectors or other components (elements), and through the avoidance of additional via through-holes, more routing space is available in each signal layer. As a result, connectors may be placed more closely, because the inter-connector routing space can be utilized more effectively since additional through-holes for vias are not needed.

Embodiments of the present invention have been described and illustrated using a full-mesh connected HPC system, as an example. Embodiments of the present inventions may also find utility in other systems that may advantageously employ a midplane, such as switching systems and others.

While the foregoing detailed description has described preferred embodiments of the present invention, it is to be understood that the above description is illustrative only and not limiting of the disclosed invention. Those of skill in this art will recognize other alternative embodiments and all such embodiments are deemed to fall within the scope of the present invention. Thus, the present invention should be limited only by the claims as set forth below.

What is claimed is:

1. A circuit board having a first side and a second side, a distance between the first and second sides defining a thickness of the circuit board, comprising:
a first surface defining a first through-hole extending from the first to the second side;
a first conductive layer disposed adjacent to the first side and covering the first surface over a first distance that is greater than half but less than the thickness of the circuit board;
a second surface defining a second through-hole that extends from the first to the second side and that is spaced away from the first through-hole;
a second conductive layer disposed adjacent to the second side covering the second surface over a second distance that is less than the thickness of the circuit board, and
a conductive signal track that directly electrically couples the first conductive layer to the second conductive layer.

2. The circuit board of claim 1, wherein the conductive signal track is oriented substantially parallel to at least one of the first and second sides.

3. The circuit board of claim 1, wherein at least a part of the first conductive layer overlaps a part of the second conductive layer.

4. The circuit board of claim 1, wherein at least a portion of the first surface that is not covered by the first conductive layer is electrically non-conductive.

5. The circuit board of claim 4, further including a third conductive layer disposed adjacent to the second side and covering the first surface over a third distance that is less than the thickness of the circuit board.

6. The circuit board of claim 5, wherein the electrically non-conductive portion of the first surface is disposed between the first and third conductive layers.

7. The circuit board of claim 1, wherein at least a portion of the second surface that is not covered by the second conductive layer is electrically non-conductive.

8. The circuit board of claim 7, further including a fourth conductive layer disposed adjacent to the first side and covering the second surface over a fourth distance that is less than the thickness of the circuit board.

9. The circuit board of claim 8, wherein the electrically non-conductive portion of the second surface is disposed between the second and fourth conductive layers.

10. The circuit board of claim 1, further comprising a first connector including a first conductive element and a second connector including a second conductive element, wherein the first conductive element is disposed within the first through-hole and electrically coupled to the first conductive layer and wherein the second conductive element is disposed within the second through-hole and electrically coupled to the second conductive layer.

11. The circuit board of claim 10, wherein the first conductive element includes a first pin and wherein the second conductive element includes a second pin.

12. The circuit board of claim 1, wherein the circuit board is a multilayer midplane.

13. The circuit board of claim 1, wherein the conductive signal track is configured to electrically couple the first conductive layer to the second conductive layer without an intervening fully plated through-hole.

14. A multilayer midplane board having a front side and a back side, comprising:
a first partially plated through-hole;
a second partially plated through-hole spaced away from the first partially plated through-hole, and
a first conductive signal track electrically coupling a selected plated section of the first partially plated through-hole directly adjacent the front side to a selected plated section of the second partially plated through-hole adjacent the back side.

15. The multilayer midplane board of claim 14, further comprising:
a first connector including a first conductive element inserted into the first partially plated through-hole from the front side, and
a second connector including a second conductive element inserted into the second partially plated through-hole from the back side, wherein the first conductive signal track electrically couples the first conductive element to the second conductive element.

16. The multilayer midplane board of claim 14, wherein the first partially plated through-hole extends from the front side to the back side and comprises a first conductive layer adjacent the front side and a second conductive layer adjacent the back side and a first non-conductive region between the first and second conductive layers.

17. The multilayer midplane board of claim 14, wherein the second partially plated through-hole extends from the front side to the back side and comprises a third conductive layer adjacent the front side and a fourth conductive layer adjacent the back side and a second non-conductive region between the third and fourth conductive layers.

18. The multilayer midplane board of claim 14, wherein the first partially plated through-hole and the second partially plated through-holes are configured such that the first conductive signal track is disposed substantially parallel to at least one of the front and back sides.

19. The multilayer midplane board of claim 14, wherein at least one of the selected plated section of the first partially plated through-hole and the selected plated section of the second partially plated through-hole extends over a distance that is greater than half but less than the thickness of the multilayer midplane board.

20. The multilayer midplane board of claim 14, further comprising a fully plated through-hole extending between the front and back sides.

21. The multilayer midplane board of claim 14, wherein the first partially plated through-hole includes a first plated section, a second plated section and a first insulated section between the first and second plated sections.

22. The multilayer midplane board of claim 21, wherein the first plated section has a same length as a length of the second plated section.

23. The multilayer midplane board of claim 21, wherein the first plated section is longer than the second plated section.

24. The multilayer midplane board of claim 14, wherein the second partially plated through-hole includes a third plated section, a fourth plated section and a second insulated section between the third and fourth plated portions.

25. The multilayer midplane board of claim 24, wherein the third plated section has a same length as a length of the fourth plated section.

26. The multilayer midplane board of claim 24, wherein the third plated section is longer than the fourth plated section.

27. The multilayer midplane board of claim 14, wherein the first partially plated through-hole includes a plated section adjacent the front side, the second partially plated through-hole includes a plated section adjacent the back side, and a sum of the lengths of the plated sections is greater than a thickness of the multilayer midplane by at least a thickness of the first conductive signal track.

28. A computer, comprising:
a plurality of compute modules;
an Input/Output module;
a multilayer midplane board including a front side and a back side, selected ones of the plurality of compute modules being coupled to the front side through respective front side connectors and selected other ones of the plurality of compute modules and the Input/Output module being coupled to the back side through respective back side connectors, wherein the multilayer midplane board includes:
a plurality of partially plated through-holes extending between the front and back sides of the multilayer midplane, each of the plurality of partially plated through-holes including a first conductive section, a second conductive section and an insulating section between the first and second conductive sections, and
a plurality of conductive signal tracks, each electrically coupling one of the first and second conductive sections of a selected one of the plurality of partially plated through-holes to one of the first and second plated sections of another one of the plurality of selected partially plated through-holes to electrically couple a selected one of the front side connectors to a selected one of the back side connectors.

29. The computer of claim 28, wherein first conductive sections are disposed adjacent the front side and wherein the second conductive sections are disposed adjacent the back side of the multilayer midplane board.

30. The computer of claim 28, wherein each of the front side connectors and the back side connectors includes at least one conductive element inserted into one of the plurality of partially plated through-holes.

31. The computer of claim 28, wherein the plurality of partially plated through-holes are configured such that the plurality of conductive signal tracks are disposed substantially parallel to at least one of the front and back sides.

32. The computer of claim 28, further comprising at least one fully plated through-hole extending between the front and back sides to directly electrically couple at least one selected front side connector to at least one selected back side connector.

33. The computer of claim 28, further comprising at least one fully plated through-hole extending between the front and back sides to directly electrically couple at least one selected front side connector to at least one selected back side connector such that each one of the plurality of compute and the Input/Output modules is electrically coupled to each of the other of the plurality of compute and the Input/Output modules.

34. The computer of claim 28, wherein each of the plurality of partially plated through-holes includes a first plated section, a second plated section and a first insulated section between the first and second plated sections.

35. The computer of claim 34, wherein the first plated section has a same length as a length of the second plated section.

36. The computer of claim 34, wherein the first plated section is longer than the second plated section.

37. The computer of claim 34, wherein at least one selected plated section of one of the plurality of partially plated through-holes extends over a distance that is greater than half but less than the thickness of the multilayer midplane board.

38. A multilayer midplane board having a first side and a second side, comprising:
a first partially plated through-hole including a first plated section adjacent the first side, a second plated section adjacent the second side and a first insulated section between the first plated section and the second plated section;
a second partially plated through-hole including a third plated section adjacent the first side, a fourth plated section adjacent the second side and a second insulated section between the third plated section and the fourth plated section;
a first conductive signal track electrically coupled to the first plated section and the fourth plated section, and
a second conductive signal track electrically coupled to the second plated section;
a third conductive signal track electrically coupled to the third plated section, the first, second and third conductive signal tracks being electrically isolated from one another.

39. The multilayer midplane board of claim 38, further comprising:
a first connector including a first conductive element inserted into the first partially plated through-hole from the first side, and
a second connector including a second conductive element inserted into the second partially plated through-hole from the second side, the first conductive signal track electrically coupling the first conductive element to the second conductive element.

40. The multilayer midplane board of claim 38, further comprising:
a first connector including a first conductive element inserted into the first partially plated through-hole from the first side, and
a second connector including a second conductive element inserted into the second partially plated through-hole from the first side, the second conductive signal track electrically coupling the first conductive element to the second conductive element.

41. The multilayer midplane board of claim 38, wherein at least one of the first and fourth plated sections extends over a distance that is greater than half but less than the thickness of the multilayer midplane board.

42. The multilayer midplane board of claim 38, further comprising a fully plated through-hole extending between the first and second sides.

43. The multilayer midplane board of claim 38, wherein the first plated section has a same length as a length of the second plated section.

44. The multilayer midplane board of claim 38, wherein the first plated section is longer than the second plated section.

45. The multilayer midplane board of claim 38, wherein the third plated section has a same length as a length of the fourth plated section.

46. The multilayer midplane board of claim 38, wherein the third plated section is longer than the fourth plated section.

47. The multilayer midplane board of claim 38, wherein a sum of the lengths of the first and second plated sections is greater than a thickness of the multilayer midplane by at least a thickness of the first conductive signal track.
